(19) United States
(12) Patent Application Publication
(10) Pub. No.: US 2004/0248401 A1
(43) Pub. Date: Dec. 9, 2004

(54) Method for forming buried wiring and semiconductor device

(75) Inventors: Mitsunari Satake, Osaka (JP); Muneyuki Matsumoto, Niigata (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/859,217

(22) Filed: Jun. 3, 2004

(30) Foreign Application Priority Data
Jun. 9, 2003 (JP) 2003-163492

(51) Int. Cl. H01L 21/4763

(52) U.S. Cl. 438/634; 438/633; 438/631; 438/629; 438/626

(57) ABSTRACT

A TaN film and a Cu film are deposited successively over an insulating film formed with trenches. Then, a first CMP process is performed by using a slurry having a polishing rate for Cu sufficiently higher than a polishing rate for TaN and containing an agent for forming a protective film for Cu in a sufficient amount. As a result, the upper surface of the portion of the Cu film located in each of the trenches is positioned flush with the upper surface of TaN. Then, a second CMP process is performed under such a condition that the polishing rate for Cu is equal to or higher than the polishing rate for TaN, thereby forming Cu wires. By properly changing conditions for the second CMP process in accordance with the level of the upper surface of the Cu film, the upper surface of the Cu film is positioned flush with or lower in level than the upper surface of the insulating film after the second CMP process so that the occurrence of defective wiring is reduced.

The present application claims priority under 35 U.S.C. § 119(a) to Japanese Patent Application JP 2003-163492, the entire content of which is incorporated herein by reference.

### BACKGROUND OF THE INVENTION

1. Field of the Invention

The present invention relates to a method for forming buried wiring (damascene wiring) using CMP (Chemical Mechanical Polishing) in the process of fabricating a semiconductor integrated circuit or the like and to a semiconductor device fabricated by using the method.

2. Description of the Related Art

With improvements in the performance of semiconductor devices, copper wiring formed by a damascene process has been used frequently in recent years. A description will be given to a prior art technology for forming damascene wiring.

FIGS. 4A to 4G are cross-sectional views illustrating the conventional process of forming buried copper wiring.

First, as shown in FIG. 4A, an oxide film 140 made of, e.g., FSG is deposited after a transistor and the like are formed on a silicon substrate. Thereafter, trenches each at a depth of, e.g., 400 nm are formed in the silicon substrate by lithography and dry etching. Then, a TaN film 141 with a thickness of about 30 nm is deposited by PVD over the entire surface of a wafer. Subsequently, Cu with a thickness of, e.g., 150 nm and Cu with a thickness of, e.g., 550 nm are deposited on the TaN film 141 by PVD and by electrolytic plating, respectively, thereby forming a Cu film 142.

Next, a first CMP process using the TaN as a stopper is performed under such a condition that a polishing rate for Cu is sufficiently higher than a polishing rate for TaN so that the upper surface of Cu in each of the trenches is either flush with the surface of TaN (see FIG. 4B) or in a depressed state (see FIG. 4E).

A factor causing the depression of the upper surface of Cu is a component for etching Cu which is contained in a slurry (abrasive solution). Specifically, the depression of the upper surface of Cu is caused by an organic acid forming a water soluble chelate complex together with Cu ions. As an example of the organic acid, glycine or the like can be listed. To ionize Cu, an oxidant such as a hydrogen peroxide is also added to the slurry.

Although the organic acid is used as a component of the slurry for the purpose of increasing the polishing rate for Cu, there are cases where a protective film forming agent for protecting the upper surface of Cu is added to the slurry as a countermeasure against roughness caused on the upper surface of Cu by the use of the organic acid. As the protective film forming agent, a quinaldic acid, piperazine, BTA (benzotriazole), or the like can be listed. A CMP process for Cu proceeds by continuously repeating the three steps of: (1) formation of a protective film; (2) exposure of a new surface of Cu by the mechanical removal of the protective film; and (3) etching of Cu using an oxidant and an organic acid. By optimizing the content of each of the components of the slurry, the upper surface of Cu can be made substantially flush with the upper surface of TaN.

Next, a second CMP process using the oxide film 140 as a stopper is performed under such a condition that the polishing rate for TaN is higher than the polishing rate for Cu and the oxide film so that Cu wires 143 are formed, as shown in FIGS. 4C and 4F. Due to the different polishing rates, each of the Cu wires 143 is formed into a protruding configuration. FIG. 4C shows a step subsequent to FIG. 4B. FIG. 4F shows a step subsequent to FIG. 4E. According to the ITRS (International Technology Roadmap for Semiconductors) 2001, a decrement in the height of a Cu wire is about 50 nm with a 0.13-μm node. As devices are miniaturized, requirements on a decrement in the height of a Cu wire has been becoming more stringent so that a process which does not involve the polishing of Cu in the second CMP process has been performed as mainstream practice. As a result, Cu may have a protruding configuration.

It is not easy to completely stop the second CMP process at the upper surface of the oxide film 140. There are cases where the oxide film 140 is polished if the composition of the slurry is not optimized, as shown in FIG. 4F. In that case, each of the Cu wires 144 naturally has a similar protruding configuration. Since the oxide film 140 is polished, the upper surface of the oxide film 140 is positioned lower in level than the upper surface of the oxide film 140 shown in FIG. 4C.

### SUMMARY OF THE INVENTION

In the case of using the conventional polishing method, however, the upper surface of Cu presents a protruding configuration halfway through the second CMP process. Since the hardness of Cu is as low as ⅙ relative to an oxide film such as FSG and 1/14 relative to TaN, there has been a possibility that the protruding Cu is mechanically dragged by a polishing pad or abrasive particles to cause wire-to-wire short circuits 145 and 146. The tendency is particularly prominent when a wire-to-wire space is minimal and wires have large widths. This may presumably be because the volume of Cu in the protruding state is larger as the widths of the wires are larger.

It is therefore an object of the present invention to provide a method for forming Cu wires with high reliability by suppressing the occurrence of defective wiring and a semiconductor device fabricated by using the method.

A method for forming buried wiring according to the present invention comprises the steps of: (a) forming a barrier metal on or above an insulating film provided on a substrate and formed with a trench and then depositing a main wiring material on the barrier metal film; (b) performing chemical mechanical polishing with respect to the main wiring material by using the barrier metal film as a stopper; and (c) after the step (b), performing chemical mechanical polishing with respect to at least the barrier metal film to form buried wiring composed of the barrier metal covering the inside of the trench and the main wiring material, conditions for the chemical mechanical polishing performed in the step (c) being changed depending on a level of an upper surface of the main wiring material when the step (b) is completed.

If polishing conditions in the step (c) are changed appropriately in accordance with a polishing situation in the step (b), the upper surface of the buried wiring is prevented from being formed into a protruding configuration and it becomes possible to reduce the frequency of the occurrence of defective wiring.

For example, an upper surface of the buried wiring is positioned flush with or lower in level than an upper surface of the insulating film except for the portion thereof located in the trench when the step (c) is completed. This achieves a reduction in the occurrence of a problem such as a short circuit between adjacent buried wires.

The upper surface of the main wiring material when the step (b) is completed is positioned substantially flush with an upper surface of the barrier metal film and chemical mechanical polishing is performed in the step (c) under such a condition that a polishing rate for the main wiring material is equal to or higher than a polishing rate for the barrier metal film. This allows the upper surface of the buried wiring to be surely positioned flush with or lower in level than the upper surface of the insulating film so that the occurrence of defective wiring is suppressed successfully.

Preferably, the slurry used for the chemical mechanical polishing in the step (b) contains abrasive particles, a hydrogen peroxide, a citric acid or glycine, and 0.6 wt % or more of a quinaldic acid.

Preferably, the slurry used for the chemical mechanical polishing in the step (c) contains abrasive particles, a hydrogen peroxide, an oxalic acid, and 0.2 wt % or less of a quinaldic acid.

In the case where the upper surface of the main wiring material when the step (b) is completed is positioned between lower and upper surfaces of the barrier metal film, if a polishing rate for the barrier metal film is a and a polishing rate for the main wiring material is b, the chemical mechanical polishing is preferably performed in the step (c) under such a condition that a ratio b/a between the polishing rate for the main wiring material and the polishing rate for the barrier metal film is more than 0 and less than 1. The method allows the upper surface of the buried wiring to be positioned flush with or lower in level than the upper surface of the insulating film and thereby achieves a reduction in the occurrence of defective wiring.

In this case, the slurry used for the chemical mechanical polishing in the step (b) contains abrasive particles, a hydrogen peroxide, a citric acid or glycine, and not less than 0.2 wt % and not more than 0.6 wt % of a quinaldic acid.

On the other hand, the slurry used for the chemical mechanical polishing in the step (c) contains abrasive particles, a hydrogen peroxide, an oxalic acid, and not less than 0.2 wt % and not more than 0.6 wt % of a quinaldic acid.

In the case where the upper surface of the main wiring material when the step (b) is completed is positioned lower in level than a lower surface of the barrier metal film, if the chemical mechanical polishing is performed in the step (c) under such a condition that the barrier metal film is performed selectively, the occurrence of defective wiring can be reduced advantageously. In this method, it is easy to control the configuration of the upper surface of the buried wiring in the step (c) such that it does not protrude.

In this case, the slurry used for the chemical mechanical polishing in the step (b) preferably contains abrasive particles, a hydrogen peroxide, a citric acid or glycine, and 0.2 wt % or less of a quinaldic acid. In particular, the setting of the concentration of the quinaldic acid to a relatively low level allows the polishing of the main wiring material even under weak polishing conditions so that the occurrence of a scratch is suppressed.

Preferably, the slurry used for the chemical mechanical polishing in the step (c) contains abrasive particles, a hydrogen peroxide, an oxalic acid, and 0.6 wt % or more of a quinaldic acid.

If a concentration of the abrasive particles contained in the slurry used for the chemical mechanical polishing in the step (c) is 5 wt % or less, the polishing of the insulating film can be prevented advantageously.

If a primary particle diameter of the abrasive particles contained in the slurry used for the chemical mechanical polishing in the step (c) is 50 nm or less, the polishing of the insulating film can be prevented advantageously.

Preferably, the slurry used for the chemical mechanical polishing in the step (c) further contains a surface active agent.

The method further comprises, prior to the step (a), the step of: forming a hard mask for forming the trench on the insulating film, wherein the chemical mechanical polishing is performed in the step (c) with respect to the hard mask simultaneously to the barrier metal film. This allows the formation of buried wiring without causing defective wiring even when the insulating film is composed of a material having low etching resistance such as a Low-k material. Accordingly, a semiconductor device in which an insulating film between wires has a reduced relative dielectric constant can be implemented.

The insulating film may further be polished by the chemical mechanical polishing in the step (c).

In the case of polishing the insulating film, the slurry used for the chemical mechanical polishing in the step (c) preferably contains abrasive particles at a concentration of 5 wt % or more.

A primary particle diameter of the abrasive particles contained in the slurry for the chemical mechanical polishing used in the step (c) is preferably 50 nm or more.

A semiconductor device according to the present invention comprises: a substrate; an insulating film provided on the substrate and formed with a trench; a barrier metal provided in the trench of the insulating film; and buried wiring provided on the barrier metal and composed of the barrier metal and a main wiring material buried in the trench, an upper surface of the main wiring material being positioned flush with or lower in level than an upper surface of the insulating film.

The arrangement achieves a reduction in wire-to-wire capacitance compared with the case where the upper surface of the main wiring material is higher in level than the upper surface of the insulating film. When the insulating film formed with the trench is a Low-k film and a diffusion preventing film composed of an SiN film or the like and having a high relative dielectric constant is provided on the insulating film and the main wiring material, the wire-to-wire capacitance can be reduced particularly greatly compared with that in the conventional semiconductor device in which the upper surface of the main wiring material is higher in level than the upper surface of the Low-k film. The arrangement also achieves a reduction in the incidence of defective wiring.

Preferably, a height difference between the upper surface of the main wiring material and the upper surface of the insulating film is not less than 0 nm and not more than 50 nm.

In particular, the upper surface of the main wiring material is preferably depressed relative to the upper surface of the insulating film.

### BRIEF DESCRIPTION OF THE DRAWINGS

FIGS. 1A to 1F are cross-sectional views illustrating a method for forming buried wiring according to a first embodiment of the present invention;

FIGS. 2A to 2F are cross-sectional views illustrating a method for forming buried wiring according to a second embodiment of the present invention;

FIGS. 3A to 3E are cross-sectional views illustrating a method for forming buried wiring according to a third embodiment of the present invention; and

FIGS. 4A to 4G are cross-sectional views illustrating the conventional process of forming buried copper wiring.

### DETAILED DESCRIPTION OF THE INVENTION

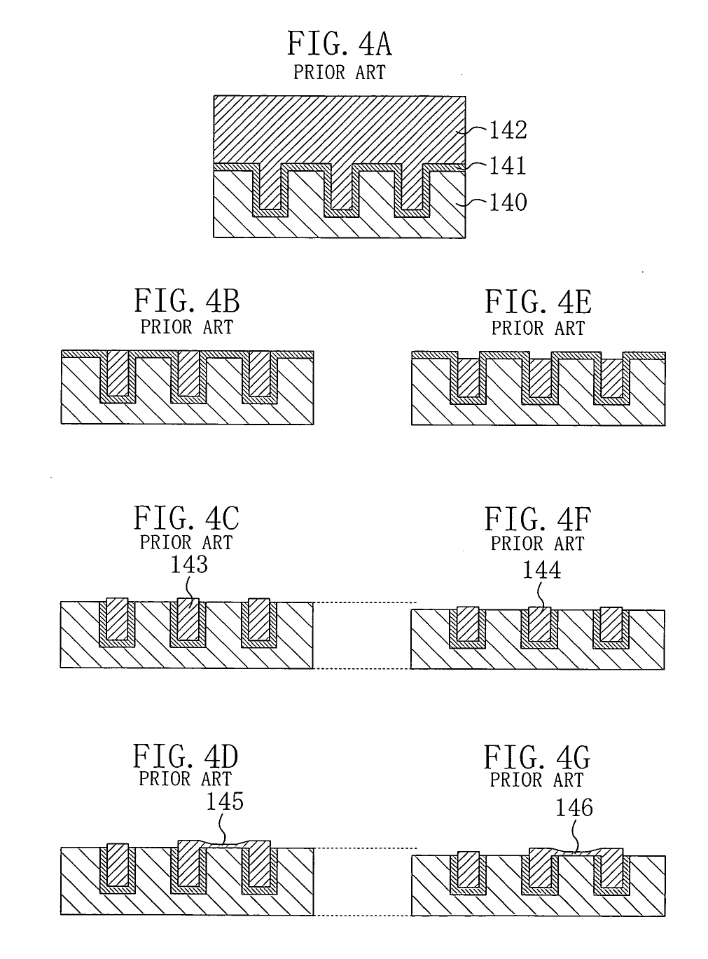

To solve the problems of the prior art technology, the present inventors attempted to improve CMP for the formation of Cu wires. As a result of making various examinations, it was found that, if a Cu film is polished by a first CMP process and then polishing conditions and the liquid composition of the slurry are changed in a second CMP process, the upper surface of each of the Cu wires can be positioned flush with or lower in level than the upper surface of the oxide film. Although the conventional method has changed the composition of the slurry between the first and second CMP processes, it has not performed the second CMP process under different conditions with respect to the substrate in the state shown in, e.g., FIG. 4B and the substrate in the state shown in, e.g., FIG. 4E.

Although it is an essential requisite that a polishing rate for Cu is higher than a polishing rate for TaN in the first CMP process, there are cases where the upper surface of a Cu wire immediately after the first CMP process is flush with or lower in level than the upper surface of a barrier film (TaN film) depending on the type or concentration of an agent for forming a protective film for Cu.

The present inventors found that it was possible to prevent a Cu wire from being formed into a protruding configuration and suppress defective wiring by changing the etching selectivity between Cu and TaN depending on the different configurations of Cu wires. A specific description will be given to the method in the following embodiments.

Embodiment 1

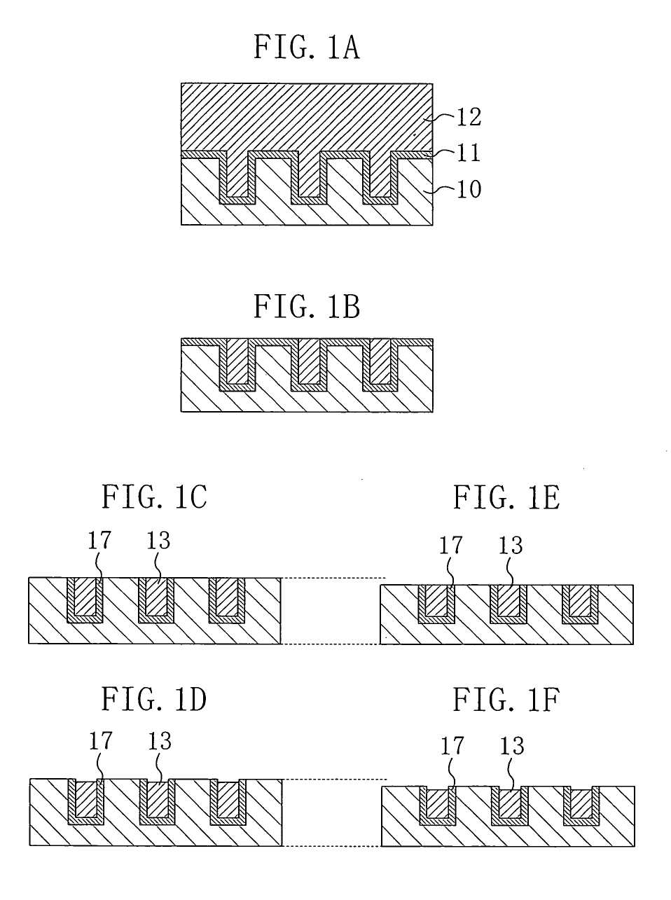

FIGS. 1A to 1F are cross-sectional views illustrating a method for forming buried wiring according to a first embodiment of the present invention.

First, as shown in FIG. 1A, a semiconductor device such as a transistor is formed on a semiconductor or insulating substrate and then an insulating film 10 made of, e.g., FSG is deposited thereon. Thereafter, trenches each at a depth of, e.g., 400 nm are formed in the insulating film 10 by lithography and dry etching. Instead of FSG, a low dielectric constant film made of a siloxane polymer, an organic polymer, a porous material, a CVD polymer, or the like may also be used as a material composing the insulating film 10.

Next, a TaN film 11 with a thickness of, e.g., 30 nm is formed as a conductive material by PVD over the entire surface of a wafer. Subsequently, Cu, e.g., is deposited as a main wiring material to a thickness of, e.g., 150 nm by PVD and to a thickness of, e.g., 550 nm by electrolytic plating to form a Cu film 12.

Instead of TaN, there may also be used tantalum, titanium, niobium, molybdenum, tungsten, or an alloy containing any of these substances, a nitride compound thereof, a carbide compound thereof, or a multilayer film thereof.

Instead of Cu, there may also be used aluminum, tungsten, silver, or an alloy containing any of these substances as a main wiring material.

Next, as shown in FIG. 1B, a first CMP process is performed by using a slurry having a polishing rate for Cu sufficiently higher than a polishing rate for TaN and containing an agent for forming a protective film for Cu in a sufficient arnount. In the first CMP process, TaN serves as a polishing stopper so that the upper surface of the portion of the Cu film located in each of the trenches is positioned substantially flush with the upper surface of the TaN film on the insulating film 10 except for the portion thereof located in the trench.

An example of the composition of the slurry used for the first CMP process is shown herein. The slurry contains silica as abrasive particles, a hydrogen peroxide as an oxidant, glycine and a quinaldic acid for forming a chelate together with Cu ions, polyalkylene imine for increasing the selectivity to TaN, and the like. Glycine is a component for increasing the polishing rate for Cu. The quinaldic acid operates as an agent for forming a protective film for Cu and is contained preferably in a proportion of 0.6 wt % or more. Since the composition of the slurry shown above is only exemplary, other compositions may also be adopted provided that the polishing rate for Cu is higher than the polishing rate for a barrier metal material such as TaN and that the etching of Cu is not accelerated.

Next, as shown in FIGS. 1C and 1D, a second CMP process using the insulating film 10 as a stopper is performed under such a condition that the polishing rate for Cu is equal to or higher than the polishing rate for TaN, thereby forming a barrier metal 17 and Cu wires 13.

In the step shown in FIGS. 1C and 1D, the insulating film 10 is barely grated and the upper surface of each of the Cu wires 13 is positioned flush with or lower in level than the upper surface of the insulating film.

An example of the composition of a slurry used for a second CMP process will be shown herein. The slurry used in the present embodiment contains silica as abrasive particles, a hydrogen peroxide as an oxidant for TaN, an oxalic acid as a reductant, and 0.2 wt % or less of a quinaldic acid as an agent for forming a protective film for Cu. The oxalic acid has the function of forming a chelate together with Cu ions and increasing the polishing rate for Cu, while the quinaldic acid conversely suppresses the polishing rate for Cu. In the case of using the slurry, the polishing rate for Cu becomes slightly higher than the polishing rate for TaN.

For the suppression of the polishing of an underlying oxide film, the concentration by weight of abrasive particles is preferably 5% or less and the primary particle diameter of particles is preferably 50 nm or less. There are also cases where a surface active agent is contained in the slurry.

By adjusting the polishing rate for Cu to be equal to or higher than the polishing rate for TaN in the second CMP process in accordance with the foregoing method, the upper surface of each of the Cu wires is prevented from being formed into a protruding configuration. As a result, a wire-to-wire short circuit can be suppressed satisfactorily because Cu has no protruding portion. The composition of the slurry is not limited to that described above provided that the polishing rate for Cu is equal to or higher than the polishing rate for TaN.

It has been mentioned heretofore that Cu is prevented from being formed into a protruding configuration in the second CMP process. A description will be given next to the degree to which a decrement in the height of each of the Cu wires is to be suppressed eventually. A decrement in the height of the wire is measured based on the following three criteria.

As the first criterion, there are numeric values disclosed in the ITRS (International Technology Roadmap for Semiconductors). According to the numeric values disclosed therein, a decrement in the height of a wire is hardly tolerated.

As the second criterion, there is a height of a Cu wire for satisfying wiring delay specifications required by an actual semiconductor device. In the case where an operating frequency is not extremely high, a decrement in the height of the Cu wire is tolerated to a certain extent. Even when the operating frequency is high, countermeasures can be taken by changing the placement of wiring.

The third criterion is whether or not a process-related problem occurs during the formation of upper-layer wiring over a region in which a Cu wire is depressed. In the event of the problem occurring, it can be solved by depositing an insulating film on the Cu wire, polishing the insulating film, and thereby reducing the depth of the depression. Hence, there should be no problem in an actual situation if the second criterion is satisfied, though the target value of a decrement in the height of the Cu wire is based on the first criterion.

FIGS. 1E and 1F show the case where the underlying insulating film is intentionally grated in the second CMP process shown in FIG. 1C. When a trench or a via is formed by dry etching, a film highly resistant to dry etching is deposited normally over the entire surface such that a decrease in the portion of the insulating film located in an unprocessed region is suppressed. This film is termed a hard mask. In the case where the insulating film to be formed with the trenches is made of FSG (with a relative dielectric constant of about 3.7), SiN (with a relative dielectric constant of about 6:5) is used to compose the hard mask. In the case where the insulating film to be formed with the trenches is made of a material having a low dielectric constant (3 or less) such as SiOC (with a relative dielectric constant of about 2.7) or the like, a plasma TEOS (with a relative dielectric constant of about 4.2), e.g., is used to compose the hard mask. In the case where the insulating film 10 is composed of a Low-k material having a relative dielectric constant of 3 or less, resistance to etching is particularly low so that it is essential to form the hard mask.

In the case of forming the hard mask, the hard mask is deposited, the trenches are formed therein, and then the TaN film and the Cu film are formed successively. Then, the Cu film is polished by the first CMP process until the TaN film overlying the hard mask is exposed. Subsequently, the TaN film, the Cu film, and the hard mask are polished in the second CMP process so that the barrier metal 17 and the Cu wires 13 are formed.

When the underlying insulating film (insulating film 10) is thus grated intentionally, a technique which increases the concentration by weight of the abrasive particles (silica) in the slurry to 5% or higher, increases the primary particle diameter to 50 nm or more, or replaces silica with alumina is used. Since alumina is harder than silica, it becomes possible to increase the polishing rate for the oxide film. The liquid component of the slurry may be the same as used in the examples shown in FIGS. 1C and 1D, but the concentration of the abrasive particles and the particle diameter are optimized such that the polishing rate for the insulating film does not exceed the polishing rate for Cu. As a result, the upper surface of each of the Cu wires 13 becomes flush with the upper surface of the insulating film, as shown in FIG. 1E, or lower in level than the upper surface of the insulating film 10, as shown in FIG. 1F.

Thus, when the upper surface of the Cu film 12 becomes substantially flush with the upper surface of the TaN film 11 as a result of the first CMP process, the method for forming buried wiring according to the present embodiment performs the second CMP process such that the polishing rate for Cu becomes equal to or higher than the polishing rate for TaN, thereby preventing the upper surface of each of the Cu wires 13 from being formed into a protruding configuration.

As shown in any one of FIGS. 1C to 1F, the semiconductor device according to the present embodiment which is fabricated by using the method for forming buried wiring described above has the insulating film 10 provided with the trenches, the barrier metal 17 covering the trenches, and the Cu wires 13 provided over the barrier metal 17 and buried in the trenches above the substrate provided with a semiconductor device such as a transistor. Here, so-called “buried wiring” is composed of the barrier metal 17 and the Cu wires 13.

In the semiconductor device according to the present embodiment, the upper surface of each of the Cu wires 13 is positioned flush with or lower in level than the upper surface of the insulating film 10. This can suppress a problem such as the occurrence of a wire-to-wire short circuit during the fabrication steps, as stated previously.

In addition, a wire-to-wire capacitance has been reduced in the semiconductor device according to the present embodiment compared with that in the conventional semiconductor device shown in FIGS. 4C to 4G. In the semiconductor device shown in FIGS. 4C to 4G, a diffusion preventing film is formed over the oxide film 140 and the Cu wires 144 in the subsequent step. In general, the diffusion preventing film is higher in relative dielectric constant than the oxide film so that a relatively large capacitance occurs between the respective portions of the adjacent Cu wires protruding from the trenches in the conventional semiconductor device having the Cu wires each formed to have the protruding upper surface. Accordingly, the wire-to-wire capacitance has been reduced and delay in operation has been suppressed in the semiconductor device according to the present embodiment compared with those in the conventional semiconductor device. These features are particularly prominent in the case where the insulating film to be formed with the trenches is a Low-k film and the insulating film of the diffusion preventing film provided on the insulating film is composed of a silicon nitride film. The foregoing advantages are common to semiconductor devices according to the other embodiments of the present invention.

In the semiconductor device according to the present embodiment, the height difference between the upper surface of each of the Cu wires 13 and that of the insulating film 10 is preferably not less than 0 nm and not more than 50 nm. This is because, if the height difference is 50 nm or more, the cross-sectional area of the Cu wire is reduced and the resistance value may be increased disadvantageously.

The upper surface of each of the Cu wires 13 is preferably depressed relative to the upper surface of the insulating film 10. If the upper surface of the Cu wire 13 is depressed, the minimum distance between the adjacent wires is substantially increased so that a wire-to-wire short circuit is prevented reliably.

Embodiment 2

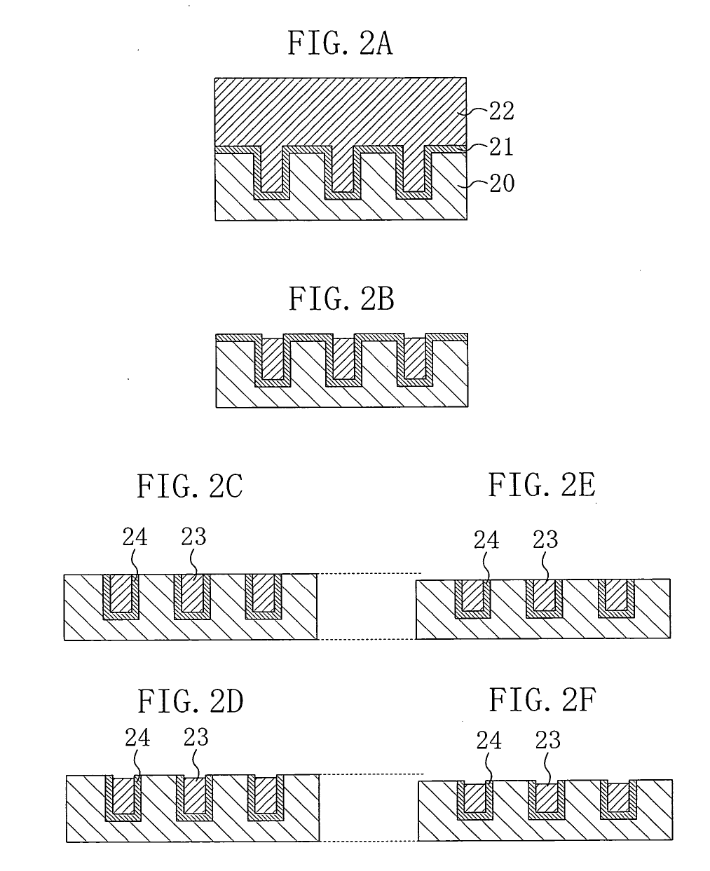

FIGS. 2A to 2F are cross-sectional views illustrating a method for forming buried wiring according to a second embodiment of the present invention.

First, as shown in FIG. 2A, a semiconductor device such as a transistor is formed on a semiconductor or insulating substrate and then an insulating film 20 made of, e.g., FSG is deposited thereon. Thereafter, trenches each at a depth of, e.g., 400 nm are formed in the insulating film 20 by lithography and dry etching. Instead of FSG, a low dielectric constant film made of a siloxane polymer, an organic polymer, a porous material, a CVD polymer, or the like may also be used as a material composing the insulating film 20.

Next, a TaN film 21 with a thickness of, e.g., 30 nm is formed as a conductive film by PVD over the entire surface of a wafer. Subsequently, Cu, e.g., is deposited as a main wiring material to a thickness of, e.g., 150 nm by PVD and to a thickness of, e.g., 550 nm by electrolytic plating to form a Cu film 22.

Instead of TaN, there may also be used tantalum, titanium, niobium, molybdenum, tungsten, or an alloy containing any of these substances, a nitride compound thereof, a carbide compound thereof, or a multilayer film thereof.

Instead of Cu, there may also be used aluminum, tungsten, silver, or an alloy containing any of these substances as a main wiring material.

Next, as shown in FIG. 2B, a first CMP process is performed by using a slurry having a polishing rate for Cu sufficiently higher than a polishing rate for TaN and containing an agent for forming a protective film for Cu in a sufficient amount. In the first CMP process, TaN serves as a polishing stopper so that the upper surface of the portion of the Cu film located in each of the trenches is positioned not lower in level than the lower surface of the TaN film provided on the insulating film 20 and not higher in level than the upper surface thereof, except for the portion thereof located in the trench.

As shown herein below, the composition of the slurry used for the first CMP process in the method according to the present embodiment is partly different from that of the slurry used in the first embodiment. The slurry used in the method according to the present embodiment contains silica as abrasive particles, a hydrogen peroxide as an oxidant, glycine and a quinaldic acid for forming a chelate together with Cu ions, polyalkylene imine for increasing the selectivity to TaN, and the like in the same manner as in the first embodiment. Glycine increases the polishing rate for Cu. The quinaldic acid operates as an agent for forming a protective film for Cu. To slightly depress Cu, the content of the quinaldic acid is adjusted to be not less than 0.2 wt % and not more than 0.6 wt %. Since the content of the quinaldic acid has been reduced in the slurry used in the present embodiment compared with that in the slurry used in the first embodiment, a proper polishing rate can be retained accordingly for Cu even when polishing conditions are weakened by decreasing a load, a relative speed, or the like. As a result, scratches in the surface of Cu can be reduced.

Next, as shown in FIG. 2C, a second CMP process using the insulating film 20 as a stopper is performed under such a condition that, if the polishing rate for TaN is a and the polishing rate for Cu is b, the ratio b/a between the polishing rate for Cu and the polishing rate for TaN is within the range of 0 to 1, thereby forming Cu wires 23. In the present step, the insulating film 20 is barely grated and the upper surface of each of the Cu wires 23 is positioned flush with (see FIG. 2C) or lower in level than (see FIG. 2D) the upper surface of the insulating film 20.

An example of the composition of a slurry used for a second CMP process will be shown herein. The slurry contains silica as abrasive particles, a hydrogen peroxide as an oxidant for TaN, an oxalic acid as a reductant, and not less than 0.2 wt % and not more than 0.6 wt % of a quinaldic acid as an agent for forming a protective film for Cu. The oxalic acid has the function of forming a chelate together with Cu ions and increasing the polishing rate for Cu, while the quinaldic acid conversely suppresses the polishing rate for Cu. An agent for forming a protective film for Cu may also be a small amount of piperadine or BTA.

In the case of using the slurry, the polishing rate for Cu becomes lower than the polishing rate for TaN and the selectivity therebetween can be adjusted by changing the ratio among the individual components of the slurry. Instead of causing the slurry to contain the agent for forming a protective film for Cu, it is also effective to, e.g., reduce the concentration of the hydrogen peroxide. To suppress the polishing of the underlying insulating film (insulating film 20), the concentration by weight of the abrasive particles is preferably adjusted to 5% or less and the primary particle diameter of the particles is preferably adjusted to 50 nm or less. There can also be adopted a method which causes the slurry to contain a surface active agent.

Since the foregoing method has retained a proper polishing rate for Cu in the second CMP process, Cu is prevented from being formed into a protruding configuration. As a result, Cu is prevented from encroaching in an adjacent trench and the occurrence of a wire-to-wire short circuit can be suppressed satisfactorily.

It has been mentioned that Cu is prevented from being formed into a protruding configuration in the second CMP process. A description will be given next to the degree to which a decrement in the height of each of the Cu wires is to be suppressed eventually. As described in the first embodiment, a decrement in the height of the wire is measured based on the following three criteria.

As the first criterion, there are numeric values disclosed in the ITRS. According to the numeric values disclosed therein, a decrement in the height of a wire is hardly tolerated.

As the second criterion, there is a height of a Cu wire for satisfying wiring delay specifications required by an actual semiconductor device. In the case where an operating frequency is not extremely high, a decrement in the height of the Cu wire is tolerated to a certain extent. Even when the operating frequency is high, countermeasures can be taken by changing the placement of wiring.

The third criterion is whether or not a process-related problem occurs during the formation of upper-layer wiring over a region in which a Cu wire is depressed. In the event of the problem occurring, it can be solved by depositing an insulating film on the Cu wire, polishing the insulating film, and thereby reducing the depth of the depression. Hence, it is sufficient in an actual situation if the second criterion is satisfied, though it is ideally preferable to satisfy the first criterion. In other words, the polishing rate for Cu may be higher than the polishing rate for TaN provided that the second criterion is satisfied.

FIGS. 2E and 2F show the case where the underlying insulating film is intentionally grated in the second CMP process shown in FIG. 2C. When a trench or a via is formed by dry etching, a film highly resistant to dry etching is deposited normally over the entire surface such that a decrease in the portion of the insulating film located in an unprocessed region is suppressed. This film is termed a hard mask. In the case where the insulating film to be formed with the trenches is made of FSG (with a relative dielectric constant of about 3.7), SiN (with a relative dielectric constant of about 6.5) is used to compose the hard mask. In the case where the insulating film to be formed with the trenches is made of a material having a low dielectric constant (3 or less) such as SiOC (with a relative dielectric constant of about 2.7) or the like, a plasma TEOS (with a relative dielectric constant of about 4.2), e.g., is used to compose the hard mask. In the case where the insulating film 20 is composed of a Low-k material having a relative dielectric constant of 3 or less, resistance to etching is particularly low so that it is essential to form the hard mask.

In the case of forming the hard mask, the hard mask is deposited, the trenches are formed therein, and then the TaN film and the Cu film are formed successively. Then, the Cu film is polished by the first CMP process until the TaN film overlying the hard mask is exposed. Subsequently, the TaN film, the Cu film, and the hard mask are polished in the second CMP process so that the barrier metal 24 and the Cu wires 23 are formed.

When the underlying insulating film (insulating film 20) is thus grated intentionally, a technique which increases the concentration by weight of the abrasive particles (silica) in the slurry to 5% or higher, increases the primary particle diameter to 50 nm or more, or replaces silica with alumina is used. In this case, the concentration of the abrasive particles and the particle diameter are optimized such that the polishing rate for the insulating film does not exceed the polishing rate for Cu. As a result, the upper surface of each of the Cu wires 23 becomes flush with the upper surface of the insulating film, as shown in FIG. 2E, or lower in level than the upper surface of the insulating film 20, as shown in FIG. 2F.

Thus, when the upper surface of the Cu film 22 is positioned not lower in level than the lower surface of TaN provided on the insulating film 20 and not higher in level than the upper surface thereof, except for the portions thereof located in the trenches, as a result of the first CMP process, the method for forming buried wiring according to the present embodiment performs the second CMP process under such a condition that retains a proper polishing rate for Cu, thereby preventing the upper surface of each of the Cu wires 23 from being formed into a protruding configuration.

Embodiment 3

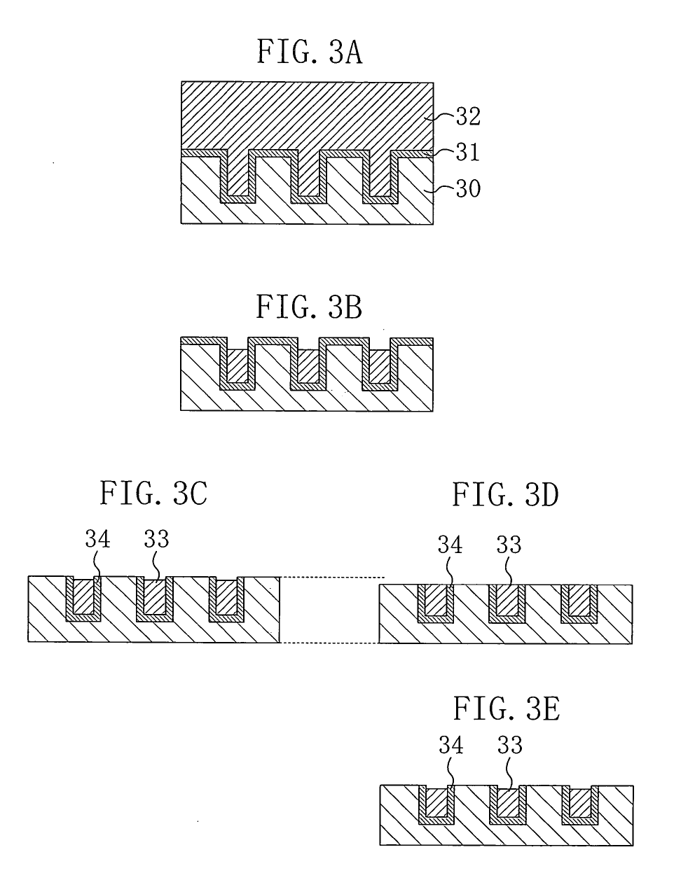

FIGS. 3A to 3E are cross-sectional views illustrating a method for forming buried wiring according to a third embodiment of the present invention.

First, as shown in FIG. 3A, a semiconductor device such as a transistor is formed on a semiconductor or insulating substrate and then an insulating film 30 made of, e.g., FSG is deposited thereon. Thereafter, trenches each at a depth of, e.g., 400 nm are formed in the insulating film 30 by lithography and dry etching. Instead of FSG, a low dielectric constant film made of a siloxane polymer, an organic polymer, a porous material, a CVD polymer, or the like may also be used as a material composing the insulating film 30.

Next, a TaN film 31 with a thickness of, e.g., 30 nm is formed as a conductive film by PVD over the entire surface of a wafer. Subsequently, Cu, e.g., is deposited as a main wiring material to a thickness of, e.g., 150 nm by PVD and to a thickness of, e.g., 550 nm by electrolytic plating to form a Cu film 32.

Instead of TaN, there may also be used tantalum, titanium, niobium, molybdenum, tungsten, or an alloy containing any of these substances, a nitride compound thereof, a carbide compound thereof, or a multilayer film thereof.

Instead of Cu, there may also be used aluminum, tungsten, silver, or an alloy containing any of these substances as a main wiring material.

Next, as shown in FIG. 3B, a first CMP process is performed by using a slurry having a polishing rate for Cu sufficiently higher than a polishing rate for TaN and containing an agent for forming a protective film for Cu in a small amount or not containing the agent at all. In the first CMP process, TaN serves as a polishing stopper so that the upper surface of the portion of the Cu film located in each of the trenches is positioned lower in level than the lower surface of the TaN film 31 provided on the insulating film 30 except for the portion thereof located in the trench. The difference between the upper surface of the Cu film and the lower surface of the TaN film 31 is preferably 50 nm or less.

As shown herein below, the composition of the slurry used for the first CMP process in the method according to the present embodiment is partly different from that of the slurry used in the first and second embodiments. The slurry used in the method according to the present embodiment contains silica as abrasive particles, a hydrogen peroxide as an oxidant, glycine for forming a chelate together with Cu ions, polyalkylene imine for increasing the selectivity to TaN, and the like. Glycine has the effect of increasing the polishing rate for Cu. If the upper surface of Cu is rough, 0.2 wt % or less of a quinaldic acid is added. Since the content of the quinaldic acid is low in the slurry used in the present embodiment, a proper polishing rate can be retained for Cu even when polishing conditions are weaker than in the first and second embodiments. As a result, scratches in the surface of Cu can be reduced.

Next, as shown in FIG. 3C, a second CMP process using the insulating film 30 as a stopper is performed under such a condition that TaN is polished selectively to Cu, thereby forming Cu wires 33. In the present step, the insulating film 30 is barely grated and the upper surface of each of the Cu wires 33 is positioned lower in level than the upper surface of the insulating film 30.

An example of the composition of a slurry used for a second CMP process will be shown herein. The slurry contains silica as abrasive particles, a hydrogen peroxide as an oxidant for TaN, an oxalic acid as a reductant, and 0.6 wt % or more of a quinaldic acid as an agent for forming a protective film for Cu. The oxalic acid has the function of forming a chelate together with Cu ions and increasing the polishing rate for Cu, while the quinaldic acid conversely suppresses the polishing rate for Cu. An agent for forming a protective film for Cu may also be piperadine or BTA. If the concentration of the hydrogen peroxide is reduced in this slurry, the polishing rate for Cu can further be suppressed. To suppress the polishing of the underlying oxide film, the concentration by weight of the abrasive particles is preferably adjusted to 5% or less and the primary particle diameter of the particles is preferably adjusted to 50 nm or less. There are cases where a surface active agent is contained in the slurry.

Since the foregoing method substantially polishes only TaN in the second CMP process, Cu is prevented from being formed into a protruding configuration. As a result, Cu is prevented from encroaching in an adjacent trench and the occurrence of a wire-to-wire short circuit can be suppressed satisfactorily.

A description will be given next to the degree to which a decrement in the height of each of the Cu wires is to be suppressed eventually. As described in the first and second embodiments, a decrement in the height of the wire is measured based on the following three criteria.

As the first criterion, there are numeric values disclosed in the ITRS. According to the numeric values disclosed therein, a decrement in the height of a wire is hardly tolerated.

As the second criterion, there is a height of a Cu wire for satisfying wiring delay specifications required by an actual semiconductor device. In the case where an operating frequency is not extremely high, a decrement in the height of the Cu wire is tolerated to a certain extent. Even when the operating frequency is high, countermeasures can be taken by changing the placement of wiring.

The third criterion is whether or not a process-related problem occurs during the formation of upper-layer wiring over a region in which the Cu wiring is depressed. In the event of the problem occurring, it can be solved by depositing an insulating film on the Cu wire, polishing the insulating film, and thereby reducing the depth of the depression. Hence, it is sufficient in an actual situation if the second criterion is satisfied, though it is ideally preferable to satisfy the first criterion. In other words, the polishing rate for Cu may be higher than in the second embodiment provided that the second criterion is satisfied.

FIGS. 3D and 3E show the case where the underlying insulating film is intentionally grated in the second CMP process shown in FIG. 3C. When a trench or a via is formed by dry etching, a hard mask highly resistant to dry etching is deposited normally over the entire surface such that a decrease in the portion of the insulating film located in an unprocessed region is suppressed. In the case where the insulating film to be formed with the trenches is made of FSG (with a relative dielectric constant of about 3.7), SiN (with a relative dielectric constant of about 6.5) is used to compose the hard mask. In the case where the insulating film to be formed with the trenches is made of a material having a low dielectric constant (3 or less) such as SiOC (with a relative dielectric constant of about 2.7) or the like, a plasma TEOS (with a relative dielectric constant of about 4.2), e.g., is used to compose the hard mask. In the case where the insulating film 30 is composed of a Low-k material having a relative dielectric constant of 3 or less, resistance to etching is particularly low so that it is essential to form the hard mask.

In the case of forming the hard mask, the hard mask is deposited, the trenches are formed therein, and then the TaN film and the Cu film are formed successively. Then, the Cu film is polished by the first CMP process until the TaN film overlying the hard mask is exposed. Subsequently, the TaN film, the Cu film, and the hard mask are polished in the second CMP process so that the barrier metal 34 and the Cu wires 33 are formed.

When the underlying insulating film (insulating film 30) is thus grated intentionally, a technique which increases the concentration by weight of the abrasive particles (silica) in the slurry to 5% or more, increases the primary particle diameter to 50 nm or more, or replaces silica with alumina is used. In this case, the concentration of the abrasive particles and the particle diameter are optimized such that the polishing rate for the insulating film does not exceed the polishing rate for Cu. As a result, the upper surface of each of the Cu wires 33 becomes flush with the upper surface of the insulating film, as shown in FIG. 3D, or lower in level than the upper surface of the insulating film 30, as shown in FIG. 3E.

If the surface of Cu in each of the trenches is positioned lower in level than the portion of the underlying insulating film grated in the first CMP process, the technique described above encounters no problem since it is necessary to suppress the polishing rate for Cu. If the surface of Cu in each of the trenches is positioned higher in level than the portion of the underlying insulating film graded in the first CMP process, however, it is necessary to adjust the slurry such that a proper polishing rate is retained for Cu and that Cu is prevented from being formed into a protruding configuration. Specifically, the concentration of the agent for forming a protective film for Cu is lowered or the concentration of the hydrogen peroxide is increased in the slurry. In this case, the configuration of each of the Cu wires 33 becomes as shown in FIG. 3E.

What is claimed is:

1. A method for forming buried wiring, the method comprising the steps of:
(a) forming a barrier metal on or above an insulating film provided on a substrate and formed with a trench and then depositing a main wiring material on the barrier metal film;
(b) performing chemical mechanical polishing with respect to the main wiring material by using the barrier metal film as a stopper; and
(c) after the step (b), performing chemical mechanical polishing with respect to at least the barrier metal film to form buried wiring composed of the barrier metal covering the inside of the trench and the main wiring material,
conditions for the chemical mechanical polishing performed in the step (c) being changed depending on a level of an upper surface of the main wiring material when the step (b) is completed.

2. The method of claim 1, wherein an upper surface of the buried wiring is positioned flush with or lower in level than an upper surface of the insulating film except for the portion thereof located in the trench when the step (c) is completed.

3. The method of claim 1, wherein
the upper surface of the main wiring material when the step (b) is completed is positioned substantially flush with an upper surface of the barrier metal film and
chemical mechanical polishing is performed in the step (c) under such a condition that a polishing rate for the main wiring material is equal to or higher than a polishing rate for the barrier metal film.

4. The method of claim 3, wherein the slurry used for the chemical mechanical polishing in the step (b) contains abrasive particles, a hydrogen peroxide, a citric acid or glycine, and 0.6 wt % or more of a quinaldic acid.

5. The method of claim 3, wherein the slurry used for the chemical mechanical polishing in the step (c) contains abrasive particles, a hydrogen peroxide, an oxalic acid, and 0.2 wt % or less of a quinaldic acid.

6. The method of claim 1, wherein
the upper surface of the main wiring material when the step (b) is completed is positioned between lower and upper surfaces of the barrier metal film and
if a polishing rate for the barrier metal film is a and a polishing rate for the main wiring material is b, the chemical mechanical polishing is performed in the step (c) under such a condition that a ratio b/a between the polishing rate for the main wiring material and the polishing rate for the barrier metal film is more than 0 and less than 1.

7. The method of claim 6, wherein the slurry used for the chemical mechanical polishing in the step (b) contains abrasive particles, a hydrogen peroxide, a citric acid or glycine, and not less than 0.2 wt % and not more than 0.6 wt % of a quinaldic acid.

8. The method of claim 6, wherein the slurry used for the chemical mechanical polishing in the step (c) contains abrasive particles, a hydrogen peroxide, an oxalic acid, and not less than 0.2 wt % and not more than 0.6 wt % of a quinaldic acid.

9. The method of claim 1, wherein
the upper surface of the main wiring material when the step (b) is completed is positioned lower in level than a lower surface of the barrier metal film and
the chemical mechanical polishing is performed in the step (c) under such a condition that the barrier metal film is polished selectively.

10. The method of claim 9, wherein the slurry used for the chemical mechanical polishing in the step (b) contains abrasive particles, a hydrogen peroxide, a citric acid or glycine, and 0.2 wt % or less of a quinaldic acid.

11. The method of claim 9, wherein the slurry used for the chemical mechanical polishing in the step (c) contains abrasive particles, a hydrogen peroxide, an oxalic acid, and 0.6 wt % or more of a quinaldic acid.

12. The method of claim 1, wherein a concentration of the abrasive particles contained in the slurry used for the chemical mechanical polishing in the step (c) is 5 wt % or less.

13. The method of claim 1, wherein a primary particle diameter of the abrasive particles contained in the slurry used for the chemical mechanical polishing in the step (c) is 50 nm or less.

14. The method of claim 1, wherein the slurry used for the chemical mechanical polishing in the step (c) further contains a surface active agent.

15. The method of claim 1, further comprising, prior to the step (a), the step of:
forming a hard mask for forming the trench on the insulating film, wherein
the chemical mechanical polishing is performed in the step (c) with respect to the hard mask simultaneously to the barrier metal film.

16. The method of claim 15, wherein the insulating film is further polished by the chemical mechanical polishing in the step (c).

17. The method of claim 16, wherein the slurry used for the chemical mechanical polishing in the step (c) contains abrasive particles at a concentration of 5 wt % or more.

18. The method of claim 16, wherein a primary particle diameter of the abrasive particles contained in the slurry used for the chemical mechanical polishing in the step (c) is 50 nm or more.

19. The method of claim 1, wherein the main wiring material is one selected from the group consisting of copper, aluminum, tungsten, silver, and an alloy containing any of these substances.

20. The method of claim 1, wherein the barrier metal film is a single-layer film or a multi-layer film composed of one material selected from the group consisting of tantalum, titanium, niobium, molybdenum, tungsten, and an alloy containing any of these substances.

21. A semiconductor device comprising:
a substrate;
an insulating film provided on the substrate and formed with a trench;
a barrier metal provided in the trench of the insulating film; and
buried wiring provided on the barrier metal and composed of the barrier metal and a main wiring material buried in the trench,
an upper surface of the main wiring material being positioned flush with or lower in level than an upper surface of the insulating film.

22. The semiconductor device of claim 21, wherein a height difference between the upper surface of the main wiring material and the upper surface of the insulating film is not less than 0 nm and not more than 50 nm.

23. The semiconductor device of claim 21, wherein the upper surface of the main wiring material is depressed relative to the upper surface of the insulating film.
